(19) United States
(12) Patent Application Publication
(10) Pub. No.: US 2025/0180674 A1
(43) Pub. Date: Jun. 5, 2025

(54) WEARABLE ELECTRONIC DEVICE COMPRISING MAGNETIC STRAP AND METHOD FOR UPDATING GEOMAGNETIC DATA

(71) Applicant: Samsung Electronics Co., Ltd., Suwon-si (KR)

(72) Inventors: Jinik KIM, Suwon-si (KR); Namjoon PARK, Suwon-si (KR); Seoyoung JIN, Suwon-si (KR)

(21) Appl. No.: 19/046,155

(22) Filed: Feb. 5, 2025

Related U.S. Application Data
(63) Continuation of application No. PCT/KR2023/011652, filed on Aug. 8, 2023.

(30) Foreign Application Priority Data
Aug. 9, 2022 (KR) 10-2022-0099475

(51) Int. Cl. G01R 33/038; A44C 5/14; G01C 17/28; G06F 1/16

(52) U.S. Cl. CPC G01R 33/0385; G01C 17/28; G06F 1/163; A44C 5/14

(57) ABSTRACT

A wearable electronic device including a magnetic strap is provided. The wearable electronic device includes a communication module, a geomagnetic sensor, a motion sensor, memory storing one or more computer programs, and one or more processors communicatively coupled to the communication module, the geomagnetic sensor, the motion sensor, and the memory, wherein one or more computer programs include computer-executable instructions that, when executed by the one or more processors individually or collectively, cause the wearable electronic device collect geomagnetic measurement values collected using the geomagnetic sensor, determine whether to update a reference magnetic field stored in the memory on the basis of offset update information of the geomagnetic sensor, when updating the reference magnetic field, designate, as reference data, geomagnetic measurement values satisfying a first condition collected within the effective time of the reference magnetic field, a second condition for collecting of magnetic field strengths within an average error range, and a third condition collected within a movement range through the motion sensor, and update the reference magnetic field based on the designated reference data.

### CROSS-REFERENCE TO RELATED APPLICATION(S)

This application is a continuation application, claiming priority under 35 U.S.C. § 365 (c), of an International application No. PCT/KR2023/011652, filed on Aug. 8, 2023, which is based on and claims the benefit of a Korean patent application number 10-2022-0099475, filed on Aug. 9, 2022, in the Korean Intellectual Property Office, the disclosure of which is incorporated by reference herein in its entirety.

### BACKGROUND

### 1. Field

The disclosure relates to a wearable electronic device including a magnetic strap and a method for updating geomagnetic reference data.

### 2. Description of Related Art

Various wearable electronic devices have been developed and released in association with electronic devices. In particular, a wearable electronic device (e.g., a watch-type electronic device) wearable on a user's wrist may be coupled to or separated from the user's body through a strap and a strap fastening part (e.g., a buckle and a latch structure).

Recently, strap fastening parts have moved away from complex structures and are being implemented with strap fastening parts using magnetic bodies (hereinafter, magnetic strap) for easier attachment and detachment.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide various functions (e.g., indoor location tracking or a compass) using sensors mounted on a mobile device or a wearable electronic device.

Additional aspects will be set forth in part in the description which follows and, in part, will be apparent from the description, or may be learned by practice of the presented embodiments.

In accordance with an aspect of the disclosure, a wearable electronic device including a magnetic strap is provided. The wearable electronic device includes a communication module, a geomagnetic sensor, a motion sensor, memory storing one or more computer programs, and one or more processors communicatively coupled to the communication module, the geomagnetic sensor, the motion sensor, and the memory, wherein the one or more computer programs include computer-executable instructions that, when executed by the one or more processors individually or collectively, cause the wearable electronic device to collect geomagnetic measurement values using the geomagnetic sensor, determine whether to update a reference magnetic field stored in the memory based on offset update information of the geomagnetic sensor, when the reference magnetic field is updated, designate, as reference data, geomagnetic measurement values satisfying a first condition collected within the effective time of the reference magnetic field, a second condition for collecting of magnetic field strengths within an average error range, and a third condition collected within a movement range set by means of the motion sensor, and update the reference magnetic field on the basis of the designated reference data.

In accordance with another aspect of the disclosure, a method for updating geomagnetic data of a wearable electronic device including a magnetic strap is provided. The method includes collecting geomagnetic measurement values using a geomagnetic sensor, determining whether to update a reference magnetic field stored in a memory, based on offset update information of the geomagnetic sensor, when the reference magnetic field is updated, designating, as reference data, geomagnetic measurement values, among the geomagnetic measurement values, satisfying a first condition collected within an effective time of the reference magnetic field, a second condition for collecting of magnetic field strengths within an average error range, and a third condition collected within a configured movement range through a motion sensor, and updating the reference magnetic field based on the designated reference data.

According to an embodiment, the wearable electronic device including a magnetic strap designates, as reference data, geomagnetic measurement values satisfying a specific condition when calculating a reference magnetic field for determining whether a horizontal external force and a vertical external force which affects magnetic field measurement, such as strap pressing, has occurred, so as to calculate the reference magnetic field, thus providing, to the user, relatively accurate azimuth angle information.

According to an embodiment, the wearable electronic device including a magnetic strap performs geomagnetic calibration by detecting a horizontal external force and a vertical external force based on the reference magnetic field with respect to the horizontal external force and the vertical external force causing geomagnetic distortion.

According to an embodiment, the geomagnetic sensor is automatically calibrated without a user input.

In accordance with another aspect of the disclosure, one or more non-transitory computer-readable storage media storing one or more computer programs including computer-executable instructions that, when executed by one or more processors of a wearable electronic device individually or collectively, cause the wearable electronic device to perform operations are provided. The operations include collecting geomagnetic measurement values using a geomagnetic sensor, determining whether to update a reference magnetic field stored in a memory, based on offset update information of the geomagnetic sensor, when the reference magnetic field is updated, designating, as reference data, geomagnetic measurement values, among the geomagnetic measurement values, satisfying a first condition collected within an effective time of the reference magnetic field, a second condition for collecting of magnetic field strengths within an average error range, and a third condition collected within a configured movement range through a motion sensor, and updating the reference magnetic field based on the designated reference data.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an example electronic device in a network environment according to an embodiment of the disclosure;

FIG. 2A illustrates components of the wearable electronic device according to an embodiment of the disclosure;

FIG. 2B illustrates an external force application situation in the wearable electronic device including a magnetic strap according to an embodiment of the disclosure;

FIG. 3 is a simplified block diagram of a wearable electronic device according to an embodiment of the disclosure;

FIG. 4A is a flowchart illustrating a disturbance detection method using reference geomagnetism updating of a wearable electronic device according to an embodiment of the disclosure;

FIG. 4B is a flowchart illustrating a method of updating a reference magnetic field of a wearable electronic device according to an embodiment of the disclosure;

FIG. 5 illustrates an accuracy and offset change amount through error calibration of a geomagnetic sensor value according to an embodiment of the disclosure;

FIG. 6 is a diagram showing geomagnetic measurement values in a three-dimensional spherical coordinate system according to an embodiment of the disclosure;

FIG. 7 illustrates a change in geomagnetic data according to a horizontal external force according to an embodiment of the disclosure;

FIG. 8 illustrates a change in geomagnetic data according to a vertical external force according to an embodiment of the disclosure;

FIG. 9 is a flowchart illustrating a method for updating an azimuth angle according to external force detection of an electronic device according to an embodiment of the disclosure; and

FIG. 10 is a flowchart illustrating a method of updating a geomagnetic data of a wearable electronic device according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

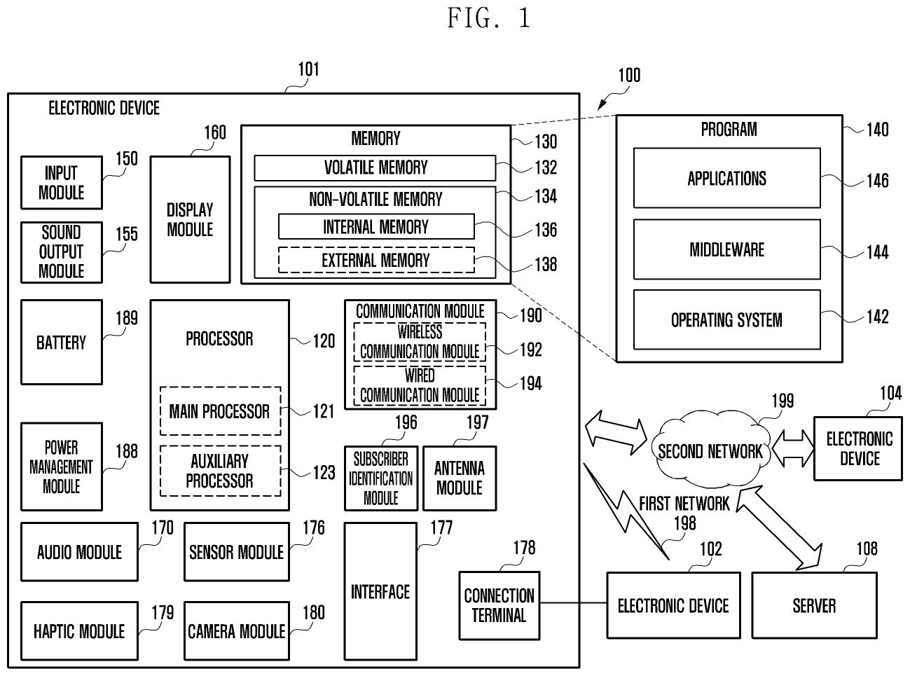

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connection terminal 178, a haptic module 179, a camera module 180, a power management module 188, a battery 189, a communication module 190, a subscriber identification module (SIM) 196, or an antenna module 197. In some embodiments, at least one of the components (e.g., the connection terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 comprises at least one processing circuitry and may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134. The memory 130 may store instructions executable by the processor 120 or the electronic device 101.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module (or display) 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 comprises at least one sensor and may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connection terminal 178 may include a connector via which the electronic device 101 may be physically connected with the external electronic device (e.g., the electronic device 102). According to an embodiment, the connection terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 comprises at least one camera and may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 comprises at least one communication circuitry and may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter-wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 comprises at least one antenna and may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

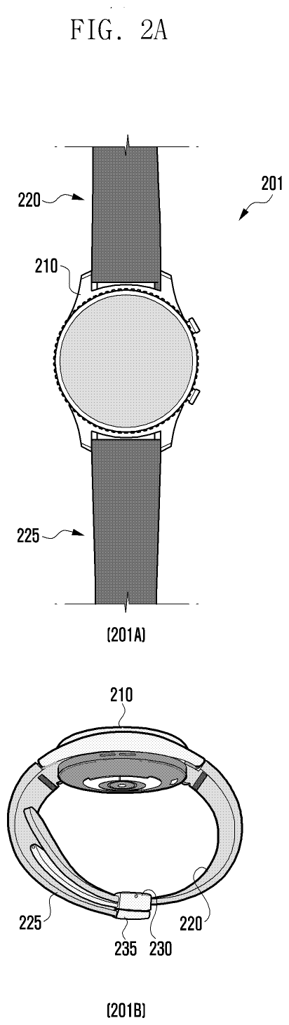

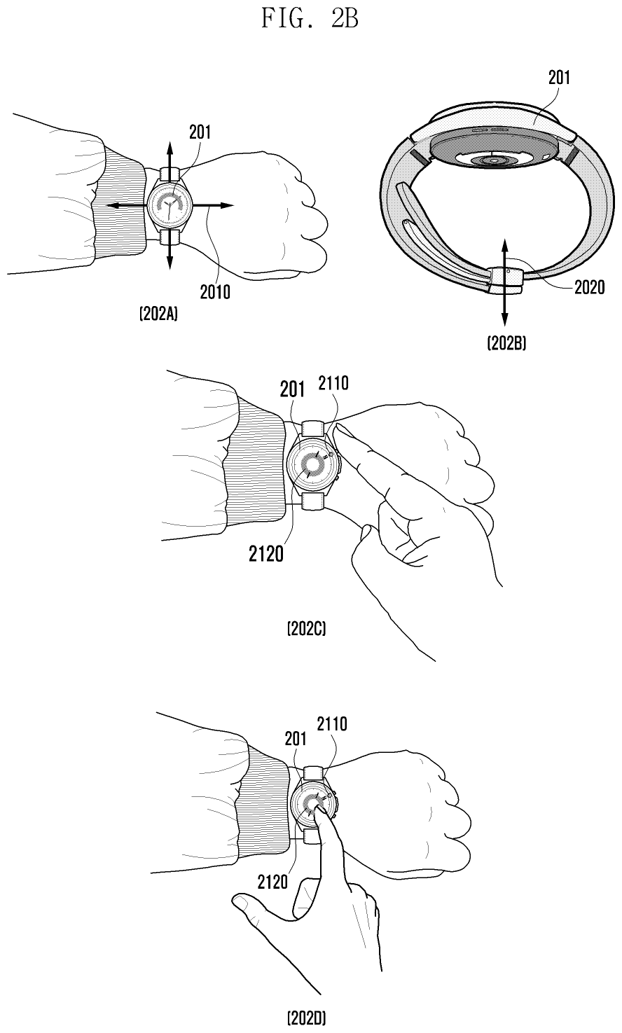

FIG. 2A illustrates components of the wearable electronic device according to an embodiment of the disclosure.

Referring to FIG. 2A, a wearable electronic device 201 (e.g., the electronic device 101 in FIG. 1) according to an embodiment may include a housing 210 and a strap 220 or 225 connected to at least a portion of the housing 210 and coupled to same to allow the wearable electronic device 201 to be fixed to or detached from a body portion (e.g., a wrist) of the user, as shown in <201A>.

According to an embodiment, the housing 210 may receive electronic components (e.g., a display, a sensor module, a communication module, a processor, and/or a memory) in an internal space thereof. For example, the housing 210 may receive the components or at least partial components shown in FIG. 1.

According to an embodiment, the strap 220 or 225 may be configured by a magnetic strap. As shown in <201B>, the strap 220 or 225 may be configured to use a strap fastening member 230 or 235 to be fixed to a body portion (e.g., a wrist) of the user. By way of example, the strap 220 or 225 may include a first strap member 220 coupled to at least a portion of the housing 210 at one side of the housing 210 and a second strap member 225 coupled to at least a portion of the housing 210 at the other side of the housing 210.

According to an embodiment, the strap fastening member 230 or 235 may be coupled to the strap 220 or 225 at least portion of the strap 220 and 225. In an embodiment, the strap fastening member 230 or 235 may include a first fastening member 230 and a second fastening member 235. The first strap 220 may include one end coupled to the housing 210 and the other end coupled to the first fastening member 230, and the second strap 225 may include one end coupled to the housing 210 and the other end coupled to the second fastening member 235.

According to an embodiment, the first fastening member 230 and the second fastening member 235 may be configured to have a fastening structure including a magnet body. For example, the fastening member 230 may receive a first magnetic (not shown) mounted thereon, and the second fastening member 235 may receive a second magnetic (not shown) mounted thereon. For another example, the first fastening member 230 and the second fastening member 235 may be configured by a material having a magnetic property.

The first fastening member 230 and the second fastening member 235 may be coupled and at least partially attached to each other in a first state. In the first state, the first magnet included in the first fastening member 230 may exert an attractive force with the second magnet included in the second fastening member 235. The first fastening member 230 and the second fastening member 235 may be coupled through the attraction force generated between the first magnet and the second magnet.

The first fastening member 230 and the second fastening member 235 may be spaced apart from each other in a second state. For example, an external force may change the first state to the second state in which the first fastening member 230 and the second fastening member 235 are spaced apart or separated from each other. In the second state, one surface of the first magnet may not be in contact with one surface of the second magnet. The first magnet included in the first fastening member 230 is spaced from the second magnet included in the second fastening member 235 in the second state so that the attraction force generated between the first magnet and the second magnet may be reduced than the first state.

FIG. 2B illustrates an external force application situation in the wearable electronic device including a magnetic strap according to an embodiment of the disclosure.

Referring to FIG. 2B, a geomagnetic sensor (not shown) that may measure the Earth's magnetic field for azimuth angle measurement is an example of a sensor mounted in an electronic device (e.g., a mobile device and the wearable electronic device). The geomagnetic sensor may detect geomagnetism by measuring a voltage value induced by geomagnetism using a fluxgate and the like, and the output value of the geomagnetic sensor may vary depending on the magnitude of a surrounding magnetic field.

However, the geomagnetic sensor is very vulnerable to external interference and may be distorted depending on the size of a surrounding magnetic field and a surrounding environment. For example, in case that a magnet is present within a predetermined distance from the geomagnetic sensor, the geomagnetic sensor may become distorted due to saturation of a magnetic force, resulting in inaccurate azimuth angles.

The magnetic strap (e.g., the strap 220 or 225 and the strap fastening member 230 or 235 in FIG. 2A) included in the wearable electronic device 201 may require a magnet body having a predetermined strength (e.g., about 450 to about 1800 gauss) or higher for fastening stability when worn and such magnetic strength may pass through the user's wrist and affect the performance of the geomagnetic sensor of the wearable electronic device 201. For example, when the user wears and uses the wearable electronic device 201, a horizontal external force 2010 (e.g., button pressing) as shown in <202A> and a vertical external force 2020 (e.g., magnetic strap pressing or watch display pressing) as shown in <202B> may cause changes in values acquired from the geomagnetic sensor.

The wearable electronic device 201 including the magnetic strap may experience a magnetic force change due to the vertical external force like strap pressing and the horizontal pressing like a button input. For example, as shown in <202C>, it may be identified that when the user presses a lateral button of the wearable electronic device 201, the magnetic force changes due to the horizontal external force because the N pole 2110 and the magnetic north 2120 of the compass (North indicated by the N pole of the compass) do not align. In addition, as shown in <202D>, it may be identified that when the user presses the front surface of the wearable electronic device 201 or due to strap pressing, the magnetic force changes due to the vertical external force because the N pole 2110 and the magnetic north 2120 of the compass (North indicated by the N pole of the compass) do not align.

It was identified that a magnetic force and an azimuth angle change due to strap pressing as shown in Table 1 through a result of measurement of a magnetic force change and an azimuth angle change after wearing the wearable electronic device 201 including the magnetic strap. In addition, even if calibration for the geomagnetic sensor is performed, in case of pressing with respect to a neighboring magnet, the change in magnetic force value causes the azimuth angle to change (e.g., a difference between the N-pole magnet and magnetic north is generated), which is recognized as an azimuth angle error. Furthermore, in case that pressure equal to or greater than 10 mm is applied to a magnet body located about 40 nm away from the geomagnetic sensor, the azimuth angle may be misaligned by up to 172 degrees, requiring re-calibration of geomagnetism.

TABLE 1

| | | Magnetic | Magnetic | Magnetic | | |
|---|---|---|---|---|---|---|
| Wrist | Pressing | force | force | force | Azimuth | Azimuth |
| thick- | amount | X-axis | Y-axis | Z-axis | angle | angle |
| ness | (mm) | value (uT) | value (uT) | value (uT) | change | error |
| 40 | 0 | 128 | −258 | −1627 | 0 | ±10 |
| mm | 1 | 127 | −264 | −1620 | −3 | degrees |
| | 2 | 124 | −273 | −1611 | −63 | |
| | 3 | 122 | −281 | −1602 | −12 | |
| | 4 | 120 | −291 | −1594 | −28 | |
| | 5 | 117 | −301 | −1584 | −71 | |
| | 6 | 114 | −311 | −1574 | −119 | |
| | 7 | 111 | −322 | −1560 | −146 | |
| | 8 | 106 | −335 | −1548 | −155 | |
| | 9 | 102 | −349 | −1534 | −160 | |
| | 10 | 95 | −368 | −1520 | −172 | |
| | 11 | 92 | −382 | −1505 | Recali- | ±15 |
| | 12 | 85 | −401 | −1490 | bration | degrees |
| | 13 | 79 | −418 | −1474 | required | |
| | 14 | 72 | −440 | −1455 | | |
| | 15 | 67 | −453 | −1437 | | |

As described above, in the case of the wearable electronic device 201 including the magnetic strap, it may be identified that an external force, such as strap pressing, causes magnetic changes, leading to errors in the geomagnetic sensor and consequently resulting in azimuth angle errors.

The geomagnetic sensor may measure a magnetic field that is different from the actual magnetic field in case of considering no distortion caused by external interference or external forces, and thus the wearable electronic device 201 may have difficulty providing azimuth angle information that accurately matches the true north of the Earth's magnetic field. In addition, the distortion due to pressure on the magnetic strap or pressure on the geomagnetic sensor may not be predicted, thus requiring adaptive calibration.

Hereinafter, various embodiments will be described with respect to a method and the wearable electronic device, by which a wearable electronic device 201 including a magnetic strap may anticipate an external force situation that may affect magnetic field measurement, and automatically calculate and update a reference magnetic field for azimuth angle calibration so that detection accuracy for geomagnetic disturbances is improved to provide relatively accurate azimuth angles.

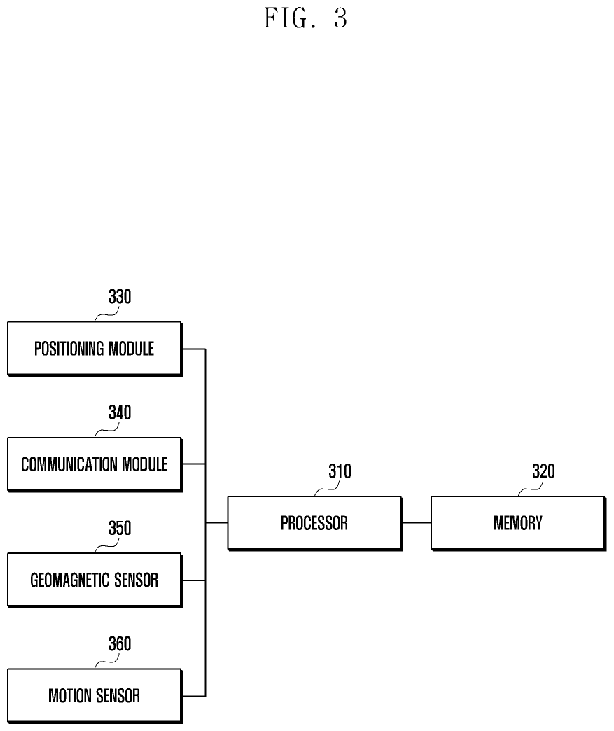

FIG. 3 is a simplified block diagram of a wearable electronic device according to an embodiment of the disclosure.

Referring to FIG. 3, a wearable electronic device 201 (e.g., the electronic device 101 in FIG. 1 and the wearable electronic device 201 in FIGS. 2A and 2B) according to an embodiment may include a processor 310 (e.g., the processor 120 in FIG. 1), a memory 320 (e.g., the memory 130 in FIG. 1), a positioning module 330, a communication module 340 (e.g., the communication module 190 in FIG. 1), a geomagnetic sensor 350, and a motion sensor 360. The wearable electronic device 201 may be implemented to have a form of the wearable electronic device in FIGS. 2A and 2B. According to an embodiment, the positioning module 330, the geomagnetic sensor 350, and the motion sensor 360 may correspond to components included in the sensor module 176 in FIG. 1.

According to an embodiment, the positioning module 330 may include a position sensor for detecting a position of the wearable electronic device 201. For example, the positioning module 330 may receive satellite information through a global navigation satellite system (GNSS) and calculate a current position of the wearable electronic device 201. According to some embodiments, the positioning module may be implemented as a portion of the communication module 340.

According to an embodiment, the communication module 340 may transmit or receive data to or from an external device. For example, the communication module 340 may receive reference magnetic field information (e.g., magnetic field information by a world magnetic model (WMM)) from an external electronic device (e.g., the electronic device 102, the electronic device 104, or the server 108 in FIG. 1). For another example, the communication module 340 may download information required for position measurement of the positioning module 330 through a network. The communication module 340 may be used for calculating a position based on a network (e.g., a mobile country code (MCC), mobile network code, GPS, Lat/Lng and/or Wi-Fi information (MNC)) in case that the positioning module 330 is not available.

According to an embodiment, the geomagnetic sensor 350 is a sensor for measuring the Earth's magnetic force (geomagnetism) and may measure a geomagnetic strength and direction (e.g., an azimuth angle). For example, the geomagnetic sensor 350 may include a 3-axis geomagnetic sensor capable of measuring geomagnetism (MₓM_{y}M_{z}) in each of the x-axis, y-axis, and z-axis.

According to an embodiment, the geomagnetic sensor 350 may be used for azimuth angle displaying. The processor 310 may use the geomagnetic sensor 350 to display direction the user is moving and/or the angle at which the user is moving when using navigation or a map and provide orientation information for east, west, south, and north when using a compass.

According to an embodiment, the motion sensor 360 may acquire motion data for measuring a signal associated with operations of the wearable electronic device 201. For example, the motion sensor 360 may include a 6-axis sensor (e.g., a 3-axis accelerometer and a 3-axis gyro sensor). The motion sensor 360 may measure at least one of axis-specific acceleration and angular velocity and acquire motion data based on the measured operation.

According to an embodiment, the memory 320 may store various information required for the operations of the wearable electronic device 201. According to an embodiment, the memory 320 may store data or information (e.g., reference magnetic field model information) required for calculating a reference magnetic field through calibration with respect to the geomagnetic sensor 350.

According to an embodiment, the processor 310 may process various operations based on the positioning module 330, the communication module 340, the geomagnetic sensor 350, and the motion sensor 360. The processor 310 may not be limited to the calculation and data processing functions required for the operations of the wearable electronic device 210, and various embodiments of the disclosure will show functions of the geomagnetic sensor 350 for determining (or calculating) a reference magnetic field and using the reference magnetic field to detect disturbances to provide a relatively accurate azimuth angle.

According to an embodiment, the processor 310 may perform calibration (e.g., initial calibration and automatic calibration) with respect to the geomagnetic sensor. For example, the processor 310 may perform calibration when there is distortion in geomagnetic measurement values collected by the geometric sensor to calculate (or re-calculate) a reference magnetic field and store the reference magnetic field in the memory 230. The processor 310 may provide a compass and navigation function by using the stored reference magnetic field.

According to an embodiment, the processor 310 may store, in the memory 320, the reference magnetic field (e.g., a first reference magnetic field) determined by performing calibration (e.g., the initial calibration) with respect to the geomagnetic sensor 350 based on the world magnetic model (WMM) acquired from an external electronic device (e.g., the electronic device 102, the electronic device 104, or the server 108 in FIG. 1).

According to an embodiment, the processor 310 may determine whether it is time to update the reference magnetic field stored in the memory based on offset update information of the geomagnetic sensor 350. The processor 310 may, in case of determining that it is time to update the reference magnetic field, designate, as reference data, geomagnetic measurement values satisfying a first condition for sampling within an effective time of the reference magnetic field, a second condition for sampling of magnetic field strengths within an average error range, and a third condition for sampling within a preconfigured movement range through the motion sensor 360 to newly calculate (or re-calculate) a reference magnetic field and update the newly determined reference magnetic field (e.g., a second reference magnetic field).

The processor 310 may store, in case that an automatic calibration procedure is started, the geomagnetic measurement values collected through the geomagnetic sensor 350 in the memory 320. The processor 310 may integrate and manage the geomagnetic measurement values satisfying a condition for determining the reference magnetic field as reference data.

According to an embodiment, the processor 310 may start the automatic calibration procedure at an offset update time point of the geomagnetic sensor and update the reference magnetic field. For example, the processor 310 may determine, as the reference magnetic field update time point, a time point when the geomagnetic sensor offset (or offset value) applied to cause the geomagnetic field measurement value to align with the reference magnetic field through error calibration is updated.

The processor 310 may identify, in case of determining the reference magnetic field update time point, an effective time configured to a currently stored reference magnetic field (e.g., the first reference magnetic field), determine, in case that the effective time of the currently stored reference magnetic field has been exceeded, a time point to determine a new reference magnetic field to detect a magnetic field strength of a geomagnetic measurement value measured within the effective time of the reference magnetic field, and determine a similarity degree of geomagnetic measurement values.

The processor 310 may determine, in case that the strength of the geomagnetic measurement value is within an average error range, whether a movement motion deviating from a preconfigured range is detected. The processor 310 may exclude the geomagnetic measurement value for the movement motion deviating from the configured range from the reference data used for determining the reference magnetic field.

The geomagnetic sensor 350 may be affected by a magnet. In case that the wearable electronic device includes the magnetic strap shown in FIGS. 2A and 2B, the geomagnetic sensor may malfunction because of geomagnetic disturbance (hereinafter, referred to as disturbance state) due to strap pressing (or an external force). In case that calibration for the geomagnetic sensor 350 is performed in the disturbance state, reference magnetic field may be configured incorrectly and an azimuth angle of an electronic device may not be accurately recognized.

According to an embodiment, the wearable electronic device (e.g., the electronic device 101 in FIG. 1 or the wearable electronic device 201 in FIGS. 2A and 3) including the magnetic strap may include a geomagnetic sensor (e.g., the sensor module 176 in FIG. 1 or the geomagnetic sensor 350 in FIG. 3), a motion sensor (e.g., the sensor module 176 in FIG. 1 or the motion sensor 30 in FIG. 3), a memory (e.g., the memory 130 in FIG. 1 or the memory 320 in FIG. 3), a communication module (e.g., the communication module 190 in FIG. 1 or the communication module 340 in FIG. 3), and a processor (e.g., the processor 120 in FIG. 1 or the processor 310 in FIG. 3) operatively connected to the geomagnetic sensor, the motion sensor, and the memory, wherein the processor is configured to collect geomagnetic measurement values collected using the geomagnetic sensor, determine whether it is time to update the reference magnetic field stored in the memory based on offset update information of the geomagnetic sensor, designate, as reference data, geomagnetic measurement values satisfying a first condition for sampling within an effective time of the reference magnetic field, a second condition for sampling of magnetic field strengths within an average error range, and a third condition for sampling within a configured movement range through the motion sensor when the reference magnetic field is updated, and update the reference magnetic field based on the designated reference data.

According to an embodiment, the reference magnetic field data may include a horizontal reference magnetic field and a vertical reference magnetic field.

According to an embodiment, the processor may be configured to, when updating the reference magnetic field, determine whether a motion of the wearable electronic device measured through the motion sensor deviates from a configured movement range, and exclude, from the reference data, outlier values acquired when the motion of the wearable electronic device deviates from the configured movement range.

According to an embodiment, the motion sensor may further include a gyro sensor and an angular velocity sensor, and the processor may be configured to compare a magnetic field strength measured through the geomagnetic sensor with a measurement value change amount, determine, when a change amount in the y-axis of the horizontal reference magnetic field deviates from a threshold, a geomagnetic disturbance state caused by the horizontal external force, calibrate an azimuth angle by using data of the gyro sensor in case of the geomagnetic disturbance state caused by the horizontal external force, and calibrate an azimuth angle by using data of the gyro sensor and the geomagnetic sensor in case of no geomagnetic disturbance state caused by the horizontal external force.

According to an embodiment, the processor may be configured to covert data in the z-axis direction among geomagnetic measurement values measured through the geomagnetic sensor into a navigation coordinate system for axis transformation, calculate the vertical reference magnetic field by using the geomagnetic data having been converted into the navigation coordinate system, determine, when a change amount in the vertical reference magnetic field deviates from a threshold, a geomagnetic disturbance state caused by the vertical external force, calibrate an azimuth angle by using data of the gyro sensor in case of the geomagnetic disturbance state caused by the vertical external force, and calibrate an azimuth angle by using data of the gyro sensor and the geomagnetic sensor in case of no geomagnetic disturbance state caused by the vertical external force.

According to an embodiment, the processor may be configured to update the horizontal reference magnetic field or the vertical reference magnetic field by using a movement average method with respect to the geomagnetic measurement values having been designated as the reference data.

According to an embodiment, the reference magnetic field stored in the memory is characterized as the reference magnetic field to which the calibration was performed based on the world magnetic model (WMM) acquired from the external electronic device.

According to an embodiment, the processor may store the reference magnetic field in the memory and then configure an effective time for the stored reference magnetic field.

According to an embodiment, the wearable electronic device may correspond to a watch-type electronic device including a first strap fastening part including a first magnet and a second strap fastening part including a second magnet.

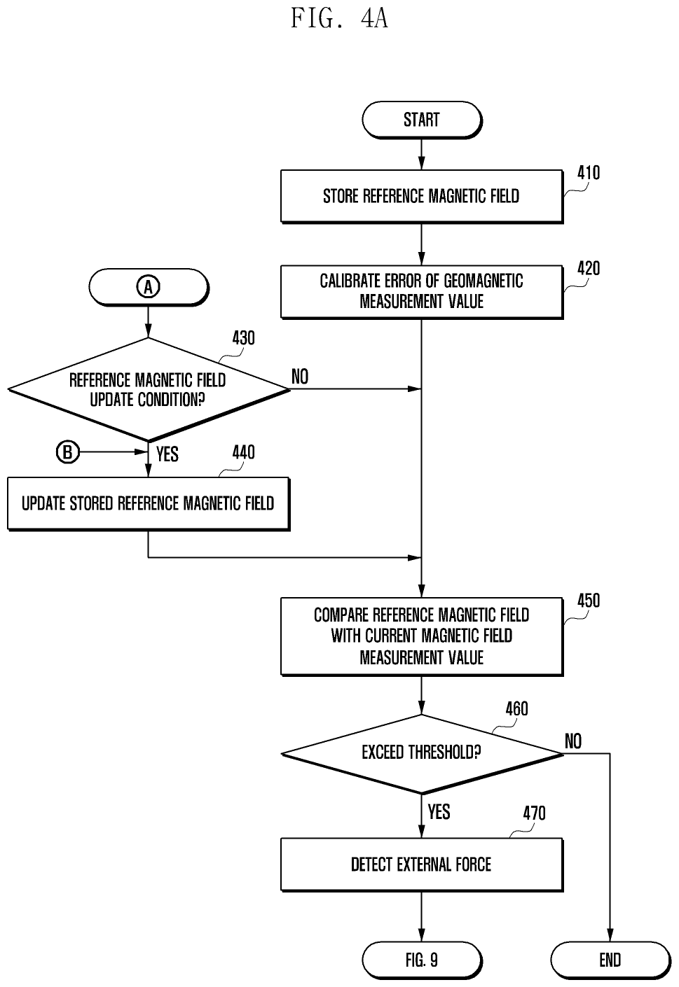

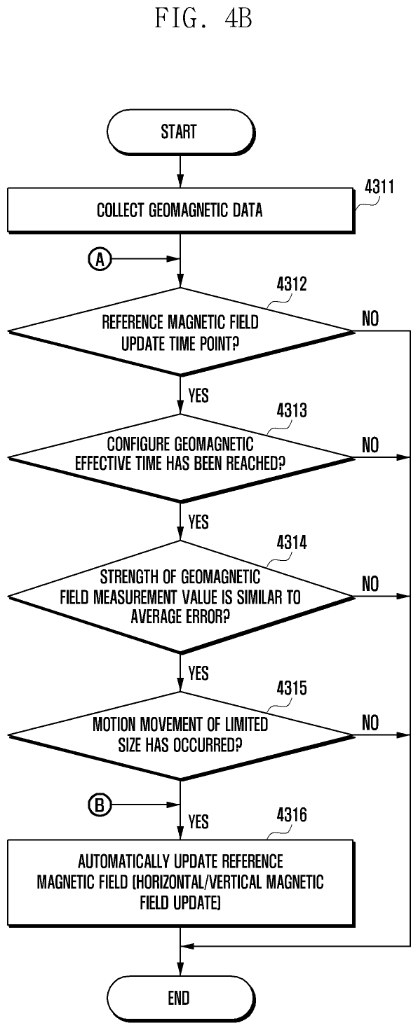

FIG. 4A is a flowchart illustrating a disturbance detection method using reference geomagnetism updating of a wearable electronic device according to an embodiment of the disclosure.

In the following embodiment, respective operations may be sequentially performed, but are not necessarily sequentially performed. For example, the sequential position of each operation may be changed, or at least two operations may be performed in parallel.

According to an embodiment, it may be understood that operation 410 to operation 470 are performed by a processor (e.g., the processor 310 in FIG. 3) of the wearable electronic device (e.g., the wearable electronic device 201 in FIGS. 2A, 2B, and 3).

Referring to FIG. 4A, according to an embodiment, a processor (e.g., the processor 310 in FIG. 3) of the wearable electronic device (e.g., the electronic device 101 in FIG. 1 or the wearable electronic device 201 in FIGS. 2A, 2B, and 3) may store a reference magnetic field (e.g., a first reference magnetic field) in a memory (e.g., the memory 320 in FIG. 3) in operation 410. The reference magnetic field stored (or configured) in the memory 320 may correspond to a reference magnetic field determined through calibration based on the world magnetic model (WMM) acquired from an external electronic device.

According to an embodiment, the processor 310 may calculate a position of the wearable electronic device 201 through a positioning module (e.g., the positioning module 330 in FIG. 3). The positioning module 330 may receive satellite information through a global navigation satellite system (GNSS) and calculate a current position of the wearable electronic device and transfer the position to the processor 310. The current position may indicate the latitude and longitude where wearable electronic device (201) is positioned. Alternatively, the processor 310 may calculate a current position of the wearable electronic device, based on a network (e.g., a mobile country code (MCC), mobile network code, GPS, Lat/Lng and/or Wi-Fi information (MNC)) in case that the positioning module is not available.

The processor 310 may perform calibration (e.g., the initial calibration) with respect to a geomagnetic sensor (e.g., the geomagnetic sensor 350 in FIG. 3) at the current position based on the world magnetic model (WMM) to calculate the reference magnetic field. For example, the processor 310 may receive WMM magnetic field information (e.g., magnetic field information by the WMM) from an external electronic device (e.g., the electronic device 102, the electronic device 104, or the server 108 in FIG. 1) through a communication module (e.g., the communication module 340 in FIG. 3). The WMM magnetic field information may be data provided from the world magnetic model (WMM) that spatially represents the Earth's magnetic field and may be estimated magnetic field information about the current position. The processor 310 may compare the geomagnetic measurement values collected through the geomagnetic sensor 350 with the magnetic field information by the WMM, calculate calibration parameters for an error when a comparison result shows that a difference equal to or greater than a configured threshold has occurred, and calculate the reference magnetic field based on the calculated calibration parameters.

The wearable electronic device 310 may provide various functions associated with a compass function and position estimation by using the reference magnetic field.

In operation 420, the processor 310 may perform error calibration with respect to data measured by the geomagnetic sensor 350. The error calibration may refer to a procedure intended to enhance the lowered accuracy of the geomagnetic sensor 310 and indicate a normalization operation. The processor 310 may use geomagnetic measurement values collected by the geomagnetic sensor 350 to update an offset value for mapping to a geomagnetic accuracy model based on the reference magnetic field. The offset value and scale value used for normalization may be configured in advance, and the offset value may be updated through error calibration.

According to an embodiment, the processor 310 may update the accuracy of the geomagnetic sensor whenever the offset value is updated through the error calibration.

Operations 430 and 440 may be performed with operations 410 and 420 in parallel or independently.

In operation 430, the processor 310 may perform a series of operations (e.g., operations between A and B) shown in FIG. 4B and may determine whether a reference magnetic field update condition has occurred. The processor 310 may perform, in case that no reference magnetic field update condition has occurred (430—No), operation 450, based on the reference magnetic field (e.g., the first reference magnetic field) stored in the memory.

The processor 310 may proceed, in case that a reference magnetic field update condition has occurred (430—Yes), to operation 440 to update the stored reference magnetic field. A series of operations associated with the reference magnetic field update will be described with reference to FIG. 4B. The processor 310 may perform, in case that the reference magnetic field has been updated through operation 440, operation 450, based on the updated reference magnetic field (e.g., the second reference magnetic field).

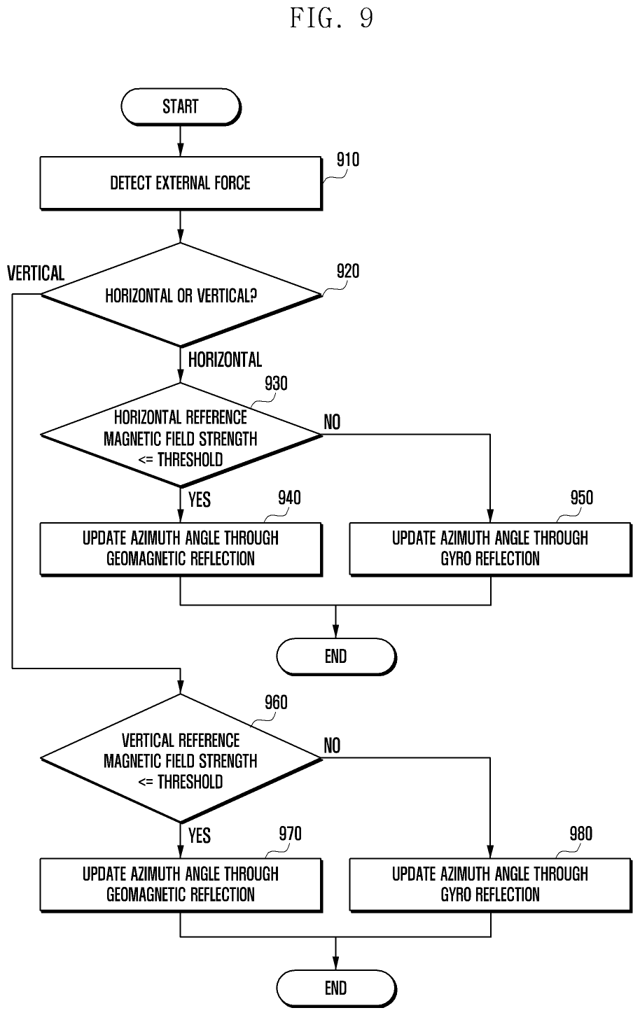

In operation 450, the processor 310 may compare a geomagnetic measurement value which is currently measured through the geomagnetic sensor 350 with the reference magnetic field. In operation 460, the processor 310 may determine, in case that the currently measured geomagnetic measurement value deviates from a designated threshold (e.g., a threshold designated for disturbance detection) range from the reference magnetic field, that an external force based on geomagnetic disturbance due to an external element has occurred. The processor 310 may proceed to FIG. 9 when an external force due to an external element is detected, and a detailed description thereof will be given with reference to FIG. 9. The processor 310 may estimate, in case that the currently measured geomagnetic measurement value does not deviate from the designated threshold from the reference magnetic field, that no external force has occurred and end the process of FIGS. 4A and 4B.

FIG. 4B is a flowchart illustrating a method of updating a reference magnetic field of a wearable electronic device according to an embodiment of the disclosure.

In the following embodiment, respective operations may be sequentially performed, but are not necessarily sequentially performed. For example, the sequential position of each operation may be changed, or at least two operations may be performed in parallel.

According to an embodiment, it may be understood that operation 4311 to operation 4316 are performed by a processor (e.g., the processor 310 in FIG. 3) of the wearable electronic device (e.g., the wearable electronic device 201 in FIGS. 2A, 2B, and 3).

Referring to FIG. 4B, the wearable electronic device 201 may determine whether the reference magnetic field has been updated and automatically update the reference magnetic field according to a designated condition. The reference magnetic field may include a horizontal reference magnetic field (the x axis and y axis) and a vertical reference magnetic field (the z axis).

In operation 4311, the processor 310 may collect a geomagnetic measurement value (or geomagnetic data) measured by the geomagnetic sensor 350. The geomagnetic measurement value may include information associated with a strength and direction of a surrounding magnetic field. The geomagnetic measurement value may have a coordinate value of MₓM_{y}M_{z} in a three-dimensional space.

In operation 4312, the processor 310 may determine an update time point of the reference magnet field, based on the offset update information. For example, the processor 310 may determine, as the reference magnetic field update time point, a time point when the offset value of the geomagnetic sensor is updated through error calibration.

According to an embodiment, the processor 310 may perform error calibration (e.g., operation 420 in FIG. 4A) for the measured data as a procedure for increasing an accuracy value with the goal of improving the lowered accuracy of the geomagnetic sensor 310.

The processor 310 may apply at least one of an offset value or a scale value to the geomagnetic measurement values collected from the geomagnetic sensor 350 to perform error calibration. For example, the processor 310 may calculate a distance (e.g., a straight-line distance on a three-dimensional spherical coordinate system) of an output value collected from the geomagnetic sensor and a preconfigured offset value and determine, in case that the calculated distance deviates from a configured range, that distortion of a measurement value has occurred, so as to perform error calibration. The geomagnetic measurement value collected from the geomagnetic sensor 350 may have a pattern similar to a figure-eight motion but is not limited thereto.

The offset value may be distorted due to surrounding influences. The processor 310 may update the offset by using a method of detecting a maximum output value and a minimum output value among geomagnetic output values and calculating a new offset value by using the detected maximum value and the minimum value. The processor 310 may determine whether distortion has occurred with respect to the updated offset value. The processor 310 may repeat procedures of determining whether offset value distortion has occurred and updating so as to enhance geomagnetic accuracy.

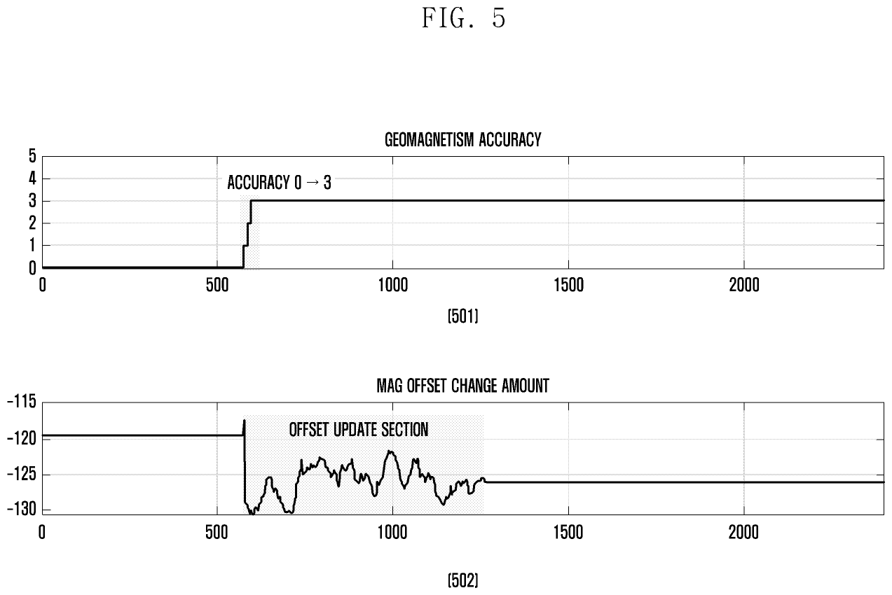

FIG. 5 illustrates an accuracy and offset change amount through error calibration of a geomagnetic sensor value according to an embodiment of the disclosure.

Referring to graph 501 of FIG. 5, the processor 310 of the wearable electronic device 201 may enhance the accuracy of the geomagnetic sensor by 0 to 3 through the error calibration of the geomagnetic sensor value. The offset value used for error calibration changes as shown in graph 502 and the offset value may be updated through the change amount. The processor may determine, as a time point to update the reference magnet field, a time point at which the offset value used for error calibration is changed, on the basis offset change amount information.

The processor 310 may end the process in case that it is not the time point to update the reference magnet field.

The processor 310 may perform, in case that it is the time point to update the reference magnet field, operation 4313 to operation 4315 to designate reference data used for calculating the reference magnet field according to a designated condition.

In operation 4313, the processor 310 may determine, in case that it is the time point to update the reference magnetic field, an effective time of the stored reference magnetic field, determine, in case that the effective time of the reference magnetic field is exceeded (e.g., a first condition), that it is a time point to determine a new reference magnetic field to proceed to operation 4314, and end the operation in case that the effective time is not exceeded.

According to an embodiment, the processor 310 may configure effective time information to the stored reference magnet field. The processor 310 may determine whether the effective time configured to the stored reference magnet field has been elapsed and determine, in case that the time configured to the configured reference magnet field has elapsed, determine that it is a time point to determine a new reference magnetic field.

In operation 4314, the processor 310 may detect a magnetic field strength of the geomagnetic measurement value measured within the effective time of the reference magnetic field and determine a similarity degree of the measurement value, and in case that the strength of the geomagnetic measurement value is similar to an average error (e.g., a second condition), proceed to operation 4315 and end the operation in case that the strength of the geomagnetic measurement value deviates from the average error.

According to an embodiment, the processor 310 may determine that it is a time point to configure a new reference magnetic field in case that the currently measured magnetic field strength is similar to the average error.

For example, the processor 310 may determine a similarity degree between the strength of the geomagnetic measurements (e.g., a radius of a sphere relative to the sphere center point) and the radius of the average error range. The similarity degree may have a value between 0 and 1, and the closer the similarity degree is to 1, the more similar the geomagnetic measurement value is.

In operation 4315, the processor 310 may determine whether a motion movement of a limited size occurs and in case that a motion movement of a limited size occurs, proceed to operation 4316, and end the operation in case that a motion movement deviates from a limited size. The processor 310 may use a geomagnetic measurement value measured by a motion movement of a limited size when updating the reference magnet field, and exclude a geomagnetic measurement value measured by a motion movement deviating from a limited range from data used for updating the reference magnetic field (e.g., a third condition).

In an embodiment, the processor 310 may detect a motion of the wearable electronic device 310 based on a motion sensor (e.g., the motion sensor 360 in FIG. 3), determine whether there is an outlier among geomagnetic measurement values by the motion of the wearable electronic device, and exclude, in case that there is an outlier, a geomagnetic measurement value for the outlier from reference data. For example, the processor 310 may use the normal distribution and standard deviation of geomagnetic measurement values to determine a value deviating from an allowable range as an outlier.

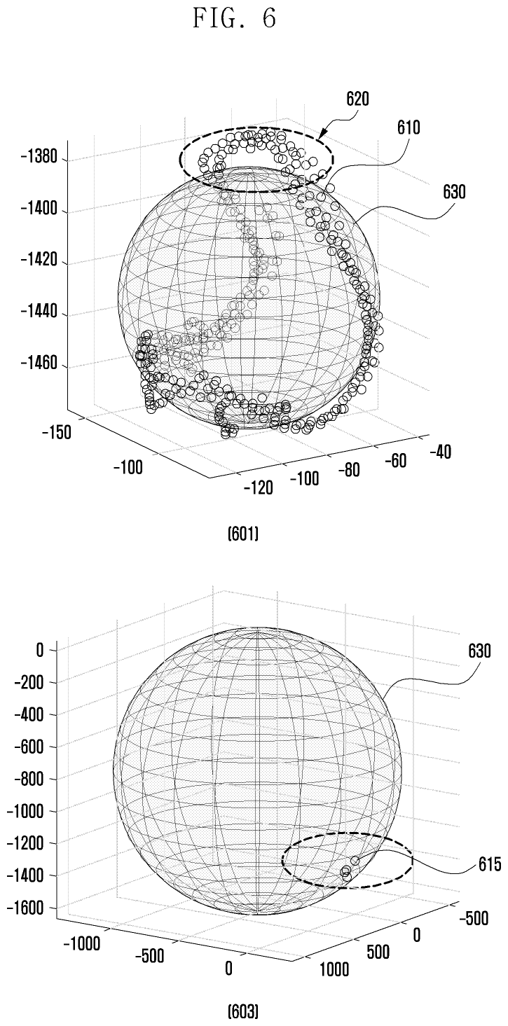

FIG. 6 is a diagram showing geomagnetic measurement values 630 in a three-dimensional spherical coordinate system 630 according to an embodiment of the disclosure.

Referring to diagram 601, it may be identified that even though the accuracy of the geomagnetic sensor is 3, among the geomagnetic measurement values 610, there is a portion 620 in which an outlier, which deviates from the radius of the spherical coordinate system 630 due to the motion of the wearable electronic device 201, has been generated. On the other hand, as shown in diagram 603, when there is no motion of the wearable electronic device 201, it may be identified that the geomagnetic measurement values 615 are included within the radius of the spherical coordinate system 630.

The processor 310 may exclude geomagnetic measurement values deviating from the radius of the spherical coordinate system 630 from the reference data used to calculate the reference magnetic field.

In operation 4316, the processor 310 may update the reference magnetic field using geomagnetic measurement values (e.g., reference data) determined based on satisfying operations 4313 to 4314. For example, the reference magnetic field may include a horizontal reference magnetic field and a vertical reference magnetic field. The horizontal reference magnetic field may be used to determine the horizontal external force, and the vertical reference magnetic field may be used to determine the vertical external force.

According to an embodiment, the processor 310 may designate geomagnetic measurement values determined based on satisfying operations 4313 to 4315 as reference data and update the reference magnetic field by using the reference data.

For example, the processor 310 may update the horizontal and vertical reference magnetic fields through a moving average method using Equation 1.

$${Ref}_{avg} ( n ) = \frac{n - 1}{n} \times {Ref}_{avg} ( n - 1 ) + \frac{1}{n} {Mes}_{new} \qquad Equation 1$$

Equation 1 is merely an example to help understanding without limitation thereto and may be modified, applied, or expanded in various manners.

In Equation 1, Mes_{new} may indicate a geomagnetic measurement value, and Ref_{avg} may indicate a reference magnetic field.

For another example, the processor 310 may calculate calibration parameters for calculating a reference magnetic field based on reference data, determine (or calculate) a reference magnetic field, and update the determined reference magnetic field (e.g., the second reference magnetic field).

According to an embodiment, the processor 310 may configure effective time information with respect to the updated reference magnet field.

For various embodiments, operations 4313 and 4314 of FIG. 4B may be omitted, operation 4313 may be omitted, or operation 4314 may be omitted.

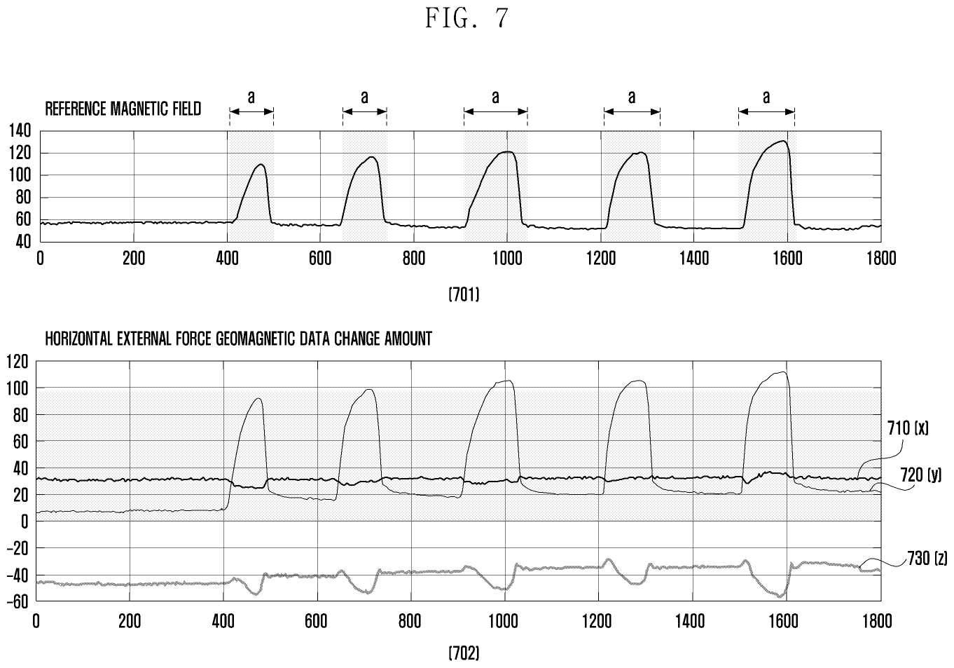

FIG. 7 illustrates a change in geomagnetic data according to a horizontal external force according to an embodiment of the disclosure.

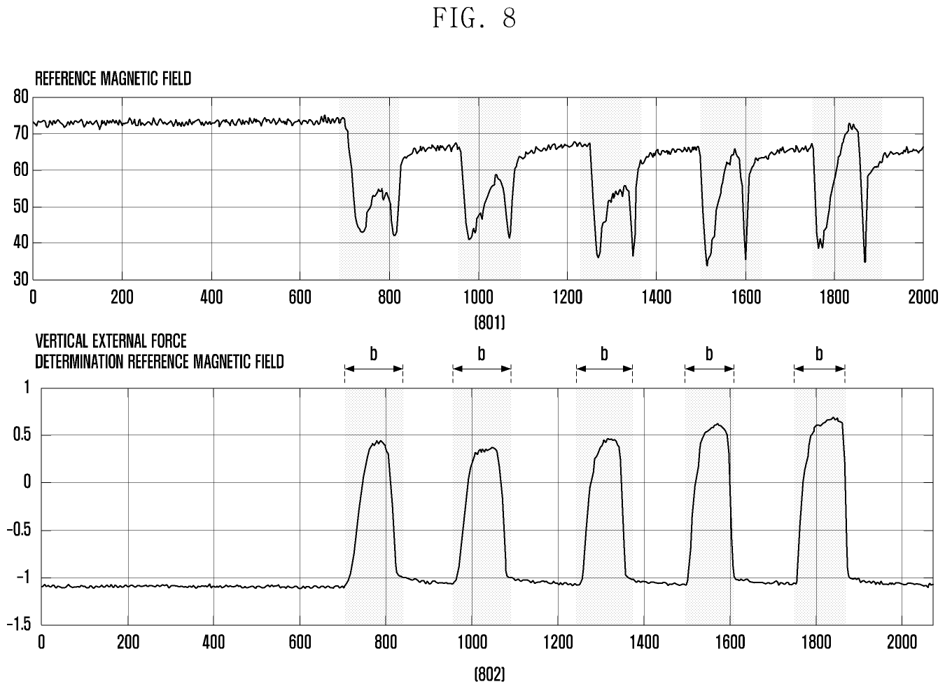

FIG. 8 illustrates a change in geomagnetic data according to a vertical external force according to an embodiment of the disclosure.

For example, as shown in FIGS. 2A and 2B, a wearable electronic device (e.g., the electronic device 101 in FIG. 1, the wearable electronic device 201 in FIGS. 2A and 2B) including a magnetic strap may experience a horizontal external force generated when the user pushes or presses the wearable electronic device 201 horizontally (e.g., pushing a lateral button portion of the wearable electronic device) and a vertical external force generated by a magnetic strap or wrist pressing (e.g., when a front plate of the wearable electronic device is pressed and/or a strap fastening device including a magnet body is pressed by the wrist).

A graph in FIG. 7 shows the change in the reference magnetic field measured by the wearable electronic device when a horizontal external force is generated. In the graph in FIG. 7, the x-axis may indicate time, and the y-axis may indicate a magnetic force. Based on 0, + and − may indicate a direction of the magnetic force, and a size of a value may indicate a strength of the magnetic force.

In case that an external force is applied in the x and y horizontal directions, the wearable electronic device 201 may perform filtering for exclusion from the reference data used to calculate the reference magnetic field through the reference magnetic field measurement value. Referring to graph 701, section <a> in the reference magnetic field measurement value is a section where the reference magnetic field changes due to a horizontal external force. In this case, as shown in graph 702, in relation to the change in geomagnetic measurement values sensed in each axis (e.g., x-axis data 710, y-axis data 720, and z-axis data 730), it may be identified that the amount of change in y is relatively large in a section where the horizontal external force is generated. The wearable electronic device 201 may calculate a difference between a horizontal reference magnetic field average and a measurement value change amount, consider the difference as data caused by the horizontal external force, and filter geomagnetic data in which the horizontal external force occurred to be excluded from the reference data.

The vertical external force caused by the magnetic strap or wrist pressing may show a different pattern from the horizontal external force. The graph in FIG. 8 shows a change in the reference magnetic field measured in the wearable electronic device when the vertical external force is generated. For example, the reference magnetic field measured when the vertical external force is generated by the magnetic strap or wrist pressing may show a pattern as shown in graph 801, so filtering using the reference magnetic field may be difficult.

According to an embodiment, the wearable electronic device 201 may perform axis transformation on the change amount in the vertical direction among geomagnetic measurement values expressed in a geomagnetic coordinate system to be displayed as a reference magnetic field. Transformation on each coordinate system may be done through Equation 2.

$$Rot ( z , ψ ) \to Rot ( y , θ ) \to ( x , Φ ) \qquad Equation 2$$

Equation 2 above is merely an example to help understanding, and is not limited thereto, and may be modified, applied, or expanded in various ways.

Here, Rot(i,j) may indicate rotation from the i axis to the j axis of a body coordinate system. The wearable electronic device 201 may convert geomagnetic measurement values into a navigation coordinate system through coordinate transformation. Here, the conversion from the body coordinate system to the navigation coordinate system may be performed through Equations 3 to 5 below.

$${c}_{b}^{n} = {c}_{h}^{n} {c}_{b}^{h} \qquad Equation 3$$

$${c}_{b}^{h} = [ \begin{matrix}cos θ & 0 & sin θ \\ 0 & 1 & 0 \\ - sin θ & 0 & cos θ\end{matrix} ] [ \begin{matrix}1 & 0 & 0 \\ 0 & cos Φ & - sin Φ \\ 0 & sin Φ & cos Φ\end{matrix} ] = [ \begin{matrix}cos θ & sin Φsinθ & cos Φsinθ \\ 0 & cos Φ & - sin Φ \\ - sin θ & sin Φcosθ & cos Φcosθ\end{matrix} ] \qquad Equation 4$$

$${c}_{h}^{n} = [ \begin{matrix}cos ψ & - sin ψ & 0 \\ sin ψ & cos ψ & 0 \\ 0 & 0 & 1\end{matrix} ] \qquad Equation 5$$

Equations 3 to 5 above are merely an example to help understanding, and is not limited thereto, and may be modified, applied, or expanded in various ways.

The wearable electronic device 201 may calculate the reference magnetic field through Equation 6 using the 3-axis geomagnetic measurement values (Mx,n,My,n Mz,n) converted to the navigation coordinate system.

$${Vertical}_{reg} = {tan}^{- 1} ( \frac{Mz , n}{norm ( Mx , n , My , n )} ) \qquad Equation 6$$

Equation 6 is merely an example to help understanding without limitation thereto and may be modified, applied, or expanded in various manners.

As shown in graph 802, in relation to the reference magnetic field measurement value calculated by the wearable electronic device 201 through axis transformation, section <b> in the reference magnetic field measurement value is a section in which the reference magnetic field changes due to a vertical external force.

The wearable electronic device 201 may calculate a difference between a vertical reference magnetic field average and a measurement value change amount, consider the difference as data caused by the vertical external force, and filter geomagnetic data in which the vertical external force occurred to be excluded from the reference data.

FIG. 9 is a flowchart illustrating a method for updating an azimuth angle according to external force detection of an electronic device according to an embodiment of the disclosure.

In the following embodiment, respective operations may be sequentially performed, but are not necessarily sequentially performed. For example, the sequential position of each operation may be changed, or at least two operations may be performed in parallel.

According to an embodiment, it may be understood that operation 910 to operation 980 are performed by a processor (e.g., the processor 310 in FIG. 3) of the wearable electronic device (e.g., the wearable electronic device 201 in FIGS. 2A, 2B, and 3).

Referring to FIG. 9, according to an embodiment, the processor 310 of the wearable electronic device (e.g., the electronic device 101 in FIG. 1 or the wearable electronic device 201 in FIGS. 2A, 2B, and 3) may detect an external force based on the reference magnet field in operation 910. Operation 910 may correspond to operation 450 in FIG. 4A.

The processor 310 may compare a geomagnetic measurement value currently being measured through a geomagnetic sensor (e.g., the geomagnetic sensor 350 in FIG. 3) with the reference magnetic field and determine, in case that the currently measured geomagnetic measurement value deviates from a designated threshold (e.g., a threshold designated for disturbance detection) range from the reference magnetic field, that an external force based on geomagnetic disturbance due to an external element has occurred.

In operation 920, the processor 310 may determine whether a horizontal external force or a vertical external force has been generated.

For example, the processor 310 may determine that a horizontal external force has been generated when a change amount in the y-axis is generated in the reference magnetic field as shown in <701> in FIG. 7, and determine that a vertical external force has been generated when a change is detected in a vertical determination reference magnetic field expressed through axis transformation as shown in <802> in FIG. 8.

In operation 930, when a horizontal external force has been generated, the processor 310 may determine whether the change amount in the horizontal reference magnetic field strength is less than or equal to a threshold. In operation 940, in case that the change amount in the horizontal reference magnetic field strength is less than or equal to a threshold, the processor 310 may consider that there is no disturbance and update or calibrate the azimuth angle using a geomagnetic sensor and a gyro sensor. In operation 950, in case that the change amount in the horizontal reference magnetic field strength deviates from a threshold, the processor 310 may consider a disturbance state and update or calibrate the azimuth angle using the gyro sensor.

In operation 960, when a vertical external force has been generated, the processor 310 may determine whether the change amount in the vertical reference magnetic field strength is less than or equal to a threshold. In operation 970, in case that the change amount in the vertical reference magnetic field strength is less than or equal to a threshold, the processor 310 may consider that there is no disturbance and update or calibrate the azimuth angle using a geomagnetic sensor and a gyro sensor. In operation 960, in case that the change amount in the horizontal reference magnetic field strength deviates from a threshold, the processor 310 may consider a disturbance state and update or calibrate the azimuth angle using the gyro sensor.

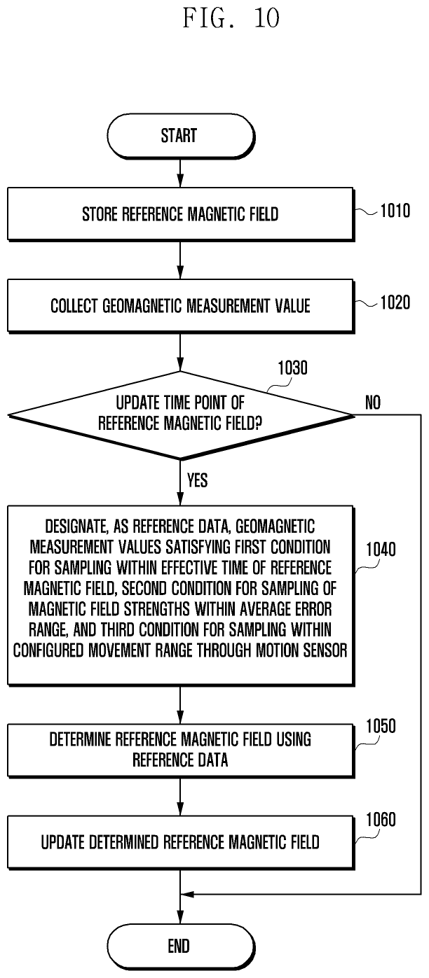

FIG. 10 is a flowchart illustrating a method of updating a geomagnetic data of a wearable electronic device according to an embodiment of the disclosure.

In the following embodiment, respective operations may be sequentially performed, but are not necessarily sequentially performed. For example, the sequential position of each operation may be changed, or at least two operations may be performed in parallel.

According to an embodiment, it may be understood that operation 1010 to operation 1060 are performed by a processor (e.g., the processor 310 in FIG. 3) of the wearable electronic device (e.g., the wearable electronic device 201 in FIGS. 2A, 2B, and 3).

Referring to FIG. 10, a processor (e.g., the processor 310 in FIG. 3) of the wearable electronic device (e.g., the electronic device 101 in FIG. 1 or the wearable electronic device 201 in FIGS. 2A, 2B, and 3) may store a reference magnetic field (e.g., a first reference magnetic field) in a memory (e.g., the memory 320 in FIG. 3) in operation 1010. The reference magnetic field stored (or configured) in the memory 320 may correspond to a reference magnetic field determined through calibration based on the world magnetic model (WMM) acquired from an external electronic device. Operation 1010 may include a series of processes described in operation 410 of FIGS. 4A and 4B.

In operation 1020, the processor 310 may collect geomagnetic measurement values acquired from a geomagnetic sensor (e.g., the geomagnetic sensor 350 in FIG. 3). Geomagnetic measurement values may include information about the strength and direction of a surrounding magnetic field and have coordinate values of in a three-dimensional space.

In operation 1030, the processor 310 may determine an update time point of the reference magnet field, based on the offset update information. In case that it is a time point to update the reference magnetic field, operation 1140 may be performed, and in case that it is not a time point to update the reference magnetic field, the process may be ended. For example, the processor 310 may determine, as the reference magnetic field update time point, a time point when an offset of the geomagnetic sensor is updated through error calibration. Operation 1130 may include a series of processes described in operation 4312 of FIGS. 4A and 4B.

In operation 1040, the processor 1040 may designate, as reference data, geomagnetic measurement values satisfying a first condition for sampling within an effective time of the reference magnetic field, a second condition for sampling of magnetic field strengths within an average error range, and a third condition for sampling within a preconfigured movement range through the motion sensor 360.

For example, the processor 310 may perform, in case that it is the time point to update the reference magnet field, operation 4313 to operation 4315 in FIGS. 4A and 4B to designate reference data used for calculating the reference magnet field according to a designated condition.

In operation 1050, the processor 310 may determine a reference magnetic field using the reference data, and in operation 1060, the processor 310 may update the determined reference magnetic field (e.g., a second reference magnetic field). For example, the reference magnetic field may include a horizontal reference magnetic field and a vertical reference magnetic field. The horizontal reference magnetic field may be used to determine the horizontal external force, and the vertical reference magnetic field may be used to determine the vertical external force. Operation 1150 may include a series of processes described in operation 4316.

A method for updating geomagnetic data of a wearable electronic device comprising a magnetic strap, according to an embodiment, may comprise collecting geomagnetic measurement values using a geomagnetic sensor. According to an embodiment, the method may comprise determining whether it is a time point to update a reference magnetic field stored in a memory, based on offset update information of the geomagnetic sensor. According to an embodiment, the method may comprise, when the reference magnetic field is updated, designating, as reference data, geomagnetic measurement values, among the geomagnetic measurement values, satisfying a first condition collected within an effective time of the reference magnetic field, a second condition for collecting of magnetic field strengths within an average error range, and a third condition collected within a configured movement range through a motion sensor. According to an embodiment, the method may comprise updating the reference magnetic field based on the designated reference data.

According to some embodiments, the reference magnetic field data comprises a horizontal reference magnetic field and a vertical reference magnetic field.

According to some embodiments, the determining of whether it is a time point to update the reference magnet field, a time point when an offset value is updated through error calibration of a geomagnetic field measurement value measured by the geomagnetic sensor is determined as the time point to update the reference magnetic field.

According to some embodiments, the designating of the measurement values satisfying the first condition, the second condition, and the third condition as the reference data, the measurement values satisfying the first condition, the second condition, and the third condition are determined as the reference data by determining an effective time of a reference magnetic field stored in a memory, determining, in case that the effective time of the reference magnetic field is exceeded, a similarity degree of geomagnetic measurement values currently being measured, and determining, in case that a strength of the geomagnetic measurement values is similar to an average error, whether there is data excluded due to a motion deviating from a configured movement range.

According to some embodiments, the designating as the reference data further comprises excluding outlier values or measurement values acquired when a motion of the wearable electronic device deviates from a configured movement range.

According to some embodiments, after the updating of the reference magnetic field, comparing a magnetic field strength measured through the geomagnetic sensor with a measurement value change amount to, in case that a change amount in the y-axis of the horizontal reference magnetic field deviates from a threshold, determine a geomagnetic disturbance state caused by a horizontal external force, calibrating an azimuth angle by using data of a gyro sensor in case of the geomagnetic disturbance state caused by the horizontal external force, and calibrating an azimuth angle by using data of the gyro sensor and the geomagnetic sensor in case of no geomagnetic disturbance state caused by the horizontal external force.

According to some embodiments, after the updating of the reference magnetic field, converting data in the z-axis direction among geomagnetic measurement values measured through the geomagnetic sensor into a navigation coordinate system for axis transformation, calculating the vertical reference magnetic field by using the geomagnetic data having been converted into the navigation coordinate system, and, in case that a change amount in the vertical reference magnetic field deviates from a threshold, determining a geomagnetic disturbance state caused by a vertical external force and calibrating an azimuth angle by using data of the gyro sensor in case of the geomagnetic disturbance state caused by the vertical external force, and calibrating an azimuth angle by using data of the gyro sensor and the geomagnetic sensor in case of no geomagnetic disturbance state caused by the vertical external force.

According to some embodiments, the updating the reference magnetic field based on the designated reference date comprises update the horizontal reference magnetic field or the vertical reference magnetic field using a movement average method with respect to the geomagnetic measurement values having been designated as the reference data.

According to some embodiments, the reference magnetic field stored in the memory corresponds to a reference magnetic field to which calibration has been performed based on a world magnetic model (WMM) acquired from an external electronic device.

It should be appreciated that various embodiments of the disclosure and the terms used therein are not intended to limit the technological features set forth herein to particular embodiments and include various changes, equivalents, or replacements for a corresponding embodiment. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A wearable electronic device comprising a magnetic strap, the wearable electronic device comprising:
a communication module;
a geomagnetic sensor;
a motion sensor;
memory storing one or more computer programs; and
one or more processors communicatively coupled to the communication module, the geomagnetic sensor, the motion sensor, and the memory,
wherein the one or more computer programs include computer-executable instructions that, when executed by the one or more processors individually or collectively, cause the wearable electronic device to:
collect geomagnetic measurement values using the geomagnetic sensor,
determine whether to update a reference magnetic field stored in the memory, based on offset update information of the geomagnetic sensor,
when the reference magnetic field is updated, designate, as reference data, geomagnetic measurement values satisfying a first condition collected within an effective time of the reference magnetic field, a second condition for collecting of magnetic field strengths within an average error range, and a third condition collected within a configured movement range through the motion sensor, and
update the reference magnetic field based on the designated reference data.

2. The wearable electronic device of claim 1, wherein the reference magnetic field comprises a horizontal reference magnetic field and a vertical reference magnetic field.

3. The wearable electronic device of claim 1, wherein the one or more computer programs further include computer-executable instructions that, when executed by the one or more processors individually or collectively, cause the wearable electronic device to:
when the reference magnetic field is updated, determine whether a motion of the wearable electronic device measured through the motion sensor deviates from a configured movement range; and
exclude, from the reference data, outlier values or measurement values acquired when the motion of the wearable electronic device deviates from the configured movement range.

4. The wearable electronic device of claim 2,
wherein the motion sensor further comprises a gyro sensor and an angular velocity sensor, and
wherein the one or more computer programs further include computer-executable instructions that, when executed by the one or more processors individually or collectively, cause the wearable electronic device to:
compare a magnetic field strength measured through the geomagnetic sensor with a measurement value change amount to determine, in case that a change amount in a y-axis of the horizontal reference magnetic field deviates from a threshold, a geomagnetic disturbance state caused by a horizontal external force,
calibrate an azimuth angle by using data of the gyro sensor in case of the geomagnetic disturbance state caused by the horizontal external force, and
calibrate an azimuth angle by using data of the gyro sensor and the geomagnetic sensor in case of no geomagnetic disturbance state caused by the horizontal external force.

5. The wearable electronic device of claim 4, wherein the one or more computer programs further include computer-executable instructions that, when executed by the one or more processors individually or collectively, cause the wearable electronic device to:
convert data in a z-axis direction among geomagnetic measurement values measured through the geomagnetic sensor into a navigation coordinate system for axis transformation;
calculate the vertical reference magnetic field by using the geomagnetic data having been converted into the navigation coordinate system;
determine, in case that a change amount in the vertical reference magnetic field deviates from a threshold, a geomagnetic disturbance state caused by a vertical external force;
calibrate an azimuth angle by using data of the gyro sensor in case of the geomagnetic disturbance state caused by the vertical external force; and
calibrate an azimuth angle by using data of the gyro sensor and the geomagnetic sensor in case of no geomagnetic disturbance state caused by the vertical external force.

6. The wearable electronic device of claim 5, wherein the one or more computer programs further include computer-executable instructions that, when executed by the one or more processors individually or collectively, cause the wearable electronic device to update the horizontal reference magnetic field or the vertical reference magnetic field using a movement average method with respect to the geomagnetic measurement values having been designated as the reference data.

7. The wearable electronic device of claim 1, wherein the reference magnetic field stored in the memory corresponds to a reference magnetic field to which calibration has been performed based on a world magnetic model (WMM) acquired from an external electronic device.

8. The electronic device of claim 1, wherein the one or more computer programs further include computer-executable instructions that, when executed by the one or more processors individually or collectively, cause the wearable electronic device to:
store the reference magnetic field in the memory, and
configure an effective time for the stored reference magnetic field.

9. The wearable electronic device of claim 1, wherein the wearable electronic device corresponds to a watch-type electronic device comprising a first strap fastening part comprising a first magnet and a second strap fastening part comprising a second magnet.

10. A method for updating geomagnetic data of a wearable electronic device comprising a magnetic strap, the method comprising:
collecting geomagnetic measurement values using a geomagnetic sensor;
determining whether to update a reference magnetic field stored in a memory, based on offset update information of the geomagnetic sensor;
when the reference magnetic field is updated, designating, as reference data, geomagnetic measurement values, among the geomagnetic measurement values, satisfying a first condition collected within an effective time of the reference magnetic field, a second condition for collecting of magnetic field strengths within an average error range, and a third condition collected within a configured movement range through a motion sensor; and
updating the reference magnetic field based on the designated reference data.

11. The method of claim 10, wherein the reference magnetic field data comprises a horizontal reference magnetic field and a vertical reference magnetic field.

12. The method of claim 10, wherein the determining of whether it is a time point to update the reference magnet field comprises determining a time point when an offset value is updated through error calibration of a geomagnetic field measurement value measured by the geomagnetic sensor as the time point to update the reference magnetic field.

13. The method of claim 10, wherein in the designating of the measurement values satisfying the first condition, the second condition, and the third condition as the reference data, the measurement values satisfying the first condition, the second condition, and the third condition are determined as the reference data by determining an effective time of a reference magnetic field stored in a memory, determining, in case that the effective time of the reference magnetic field is exceeded, a similarity degree of geomagnetic measurement values currently being measured, and determining, in case that a strength of the geomagnetic measurement values is similar to an average error, whether there is data excluded due to a motion deviating from a configured movement range.

14. The method of claim 10, wherein the designating as the reference data further comprises excluding outlier values or measurement values acquired when a motion of the wearable electronic device deviates from a configured movement range.

15. The method of claim 10, further comprising after the updating of the reference magnetic field:
comparing a magnetic field strength measured through the geomagnetic sensor with a measurement value change amount to, in case that a change amount in a y-axis of a horizontal reference magnetic field deviates from a threshold, determine a geomagnetic disturbance state caused by a horizontal external force;
calibrating an azimuth angle by using data of a gyro sensor in case of the geomagnetic disturbance state caused by the horizontal external force, and calibrating an azimuth angle by using data of the gyro sensor and the geomagnetic sensor in case of no geomagnetic disturbance state caused by the horizontal external force;
converting data in a z-axis direction among geomagnetic measurement values measured through the geomagnetic sensor into a navigation coordinate system for axis transformation, calculating a vertical reference magnetic field by using the geomagnetic data having been converted into the navigation coordinate system, and, in case that a change amount in the vertical reference magnetic field deviates from a threshold, determining a geomagnetic disturbance state caused by a vertical external force; and
calibrating an azimuth angle by using data of the gyro sensor in case of the geomagnetic disturbance state caused by the vertical external force, and calibrating an azimuth angle by using data of the gyro sensor and the geomagnetic sensor in case of no geomagnetic disturbance state caused by the vertical external force.

16. The method of claim 10, further comprising:
when the reference magnetic field is updated, determining whether a motion of the wearable electronic device measured through the motion sensor deviates from a configured movement range; and
excluding, from the reference data, outlier values or measurement values acquired when the motion of the wearable electronic device deviates from the configured movement range.

17. The method of claim 10, wherein the reference magnetic field stored in the memory corresponds to a reference magnetic field to which calibration has been performed based on a world magnetic model (WMM) acquired from an external electronic device.

18. The method of claim 10, further comprising:
storing the reference magnetic field in the memory, and
configuring an effective time for the stored reference magnetic field.

19. One or more non-transitory computer-readable storage media storing one or more computer programs including computer-executable instructions that, when executed by one or more processors of a wearable electronic device individually or collectively, cause the wearable electronic device to perform operations, the operations comprising:
collecting geomagnetic measurement values using a geomagnetic sensor;
determining whether to update a reference magnetic field stored in a memory, based on offset update information of the geomagnetic sensor;
when the reference magnetic field is updated, designating, as reference data, geomagnetic measurement values, among the geomagnetic measurement values, satisfying a first condition collected within an effective time of the reference magnetic field, a second condition for collecting of magnetic field strengths within an average error range, and a third condition collected within a configured movement range through a motion sensor; and
updating the reference magnetic field based on the designated reference data.

20. The one or more non-transitory computer-readable storage media of claim 19, wherein the reference magnetic field data comprises a horizontal reference magnetic field and a vertical reference magnetic field.
